(19) United States
(12) Patent Application Publication
(10) Pub. No.: US 2026/0206372 A1
(43) Pub. Date: Jul. 16, 2026

(54) SEMICONDUCTOR LIGHT-EMITTING ELEMENT AND DISPLAY DEVICE

(71) Applicant: LG ELECTRONICS INC., Seoul (KR)

(72) Inventors: Byoungkwon CHO, Seoul (KR); Youngsung YANG, Seoul (KR); Jinhyuk JUNG, Seoul (KR); Wonseok CHOI, Seoul (KR)

(73) Assignee: LG ELECTRONICS INC., Seoul (KR)

(21) Appl. No.: 19/136,639

(22) PCT Filed: Dec. 8, 2022
(86) PCT No.: PCT/KR2022/019886

§ 371 Date: Jun. 6, 2025

(51) Int. Cl. H10H 20/841

(52) U.S. Cl. CPC H10H 20/841

(57) ABSTRACT

The semiconductor light-emitting element may include a light-emitting layer, a passivation layer surrounding the light-emitting layer, a first electrode under the light-emitting layer, and a second electrode on the light-emitting layer. The first electrode may include a reflective layer, an adhesive layer between the light-emitting layer and the reflective layer, and a magnetic layer on the reflective layer. In this way, since the adhesive layer is disposed between the light-emitting layer and the reflective layer, the reflective layer may be firmly fixed to the light-emitting layer by the adhesive layer, so that the peeling of the reflective layer can be fundamentally prevented. In addition, as an area of the reflective layer increases, it can be more affected by the DEP force due to the metal of the reflective layer, thereby improving the assembly yield.

### TECHNICAL FIELD

The embodiment relates to a semiconductor light-emitting element and a display device.

### BACKGROUND ART

A large-area display includes a liquid crystal display (LCD), an OLED display, and a micro-LED display.

A micro-LED display is a display that uses micro-LEDs, which are semiconductor light-emitting elements with a diameter or cross-sectional area of 100um or less, as display elements.

Since the micro-LED display uses the micro-LEDs, which are the semiconductor light-emitting elements, as the display elements, it has excellent performance in many characteristics such as contrast ratio, response speed, color reproducibility, viewing angle, brightness, resolution, lifespan, light emission efficiency, or luminance.

In particular, the micro-LED display has the advantage of being able to freely adjust the size or resolution by separating and combining the screens in a modular manner, and the advantage of being able to implement a flexible display.

However, since a large micro-LED display requires millions or more micro-LEDs, there is a technical problem that makes it difficult to quickly and accurately transfer micro-LEDs to a display panel.

Recently developed transfer technologies include the pick and place process, the laser lift-off method, or the self-assembly method.

Among these, the self-assembly method is a method in which semiconductor light-emitting elements find their assembly positions within a fluid, which is advantageous for implementing large-screen display devices.

However, research on the technology for manufacturing displays through self-assembly of micro-LEDs is still insufficient.

In particular, in the case of rapidly transferring millions or more semiconductor light-emitting elements to a large display in a conventional technology, the transfer speed can be improved, but the transfer error rate can increase, which lowers the transfer yield, which is a technical problem.

In the related technology, a self-assembly transfer process using dielectrophoresis (DEP) is being attempted, but there is a problem that the self-assembly rate is low due to the non-uniformity of the DEP force.

On the other hand, there is a problem that the luminance decreases as the size of the micro-LED decreases. Accordingly, a method to increase the luminance while reducing the size of the micro-LED is being studied.

As an example, a reflector is provided on the display panel to compensate for the decrease in luminance of the micro-LED. However, since the reflector must be installed on the display panel, there is a problem that the structure becomes complicated and the thickness increases.

To solve this problem, a reflective metal is formed on a lower side of the micro-LED to increase the luminance through the reflection of the light of the micro-LED.

However, as illustrated in FIG. 1, there is a problem that the adhesion between the reflective metal 5 and the epi layer 3 (or the light-emitting layer) of the micro-LED 1 is poor, so that the reflective metal 5 is easily peeled off from the epi layer 3.

### DISCLOSURE

### Technical Problem

An object of the embodiment is to solve the foregoing and other problems.

Another object of the embodiment is to provide a semiconductor light-emitting element and a display device capable of preventing the peeling of a reflective layer.

In addition, another object of the embodiment is to provide a semiconductor light-emitting element and a display device capable of improving light efficiency and luminance.

In addition, another object of the embodiment is to provide a semiconductor light-emitting element and a display device capable of improving an assembly rate.

In addition, another object of the embodiment is to provide a semiconductor light-emitting element and a display device capable of improving a device's driving characteristics.

The technical problems of the embodiments are not limited to those described in this item and comprise those that may be understood through the description of the invention.

### Technical Solution

According to one aspect of the embodiment to achieve the above or other objects, a semiconductor light-emitting element, comprising: a light-emitting layer; a passivation layer configured to surround the light-emitting layer; a first electrode under the light-emitting layer; and a second electrode on the light-emitting layer, wherein the first electrode comprises: a reflective layer; an adhesive layer between the light-emitting layer and the reflective layer; and a magnetic layer on the reflective layer.

The reflection layer may comprise a first reflection layer on a side surface of the light-emitting layer, and the adhesive layer may be disposed between the side surface of the light-emitting layer and the first reflection layer.

The reflection layer may comprise a second reflection layer on a lower surface of the light-emitting layer, and the adhesive layer may be disposed between the lower surface of the light-emitting layer and the second reflection layer.

The adhesive layer may be disposed along an edge region of a lower surface of the light-emitting layer.

The adhesive layer may comprise a transparent conductor. The adhesive layer may have a hydrophilic surface. The adhesive layer may have a thickness of 20 nm or less.

A part of the reflective layer may be disposed on the passivation layer.

The semiconductor light-emitting element may comprise an anti-aggregation layer under the first electrode.

The anti-aggregation layer may comprise an insulator. The anti-aggregation layer may cover the first electrode.

A part of the anti-aggregation layer may be disposed on the passivation layer. The anti-aggregation layer may have a thickness of 1/10 or less of the thickness of the passivation layer.

According to another aspect of the embodiment, a display device may comprise the semiconductor light-emitting element.

### Advantageous Effects

According to the embodiment, as illustrated in FIG. 8, an adhesive layer 154-2 may be disposed on a lateral part of the light-emitting layer 150a. Accordingly, the reflective layer 154-1 may be more firmly adhered to the light-emitting layer 150a by the adhesive layer 154-2, so that the peeling of the reflective layer 154-1 can be prevented. In particular, the end of the reflective layer 154-1 may be positioned on the lateral part of the light-emitting layer 150a, and the end of the reflective layer 154-1 may be easily peeled. Therefore, according to the embodiment, since the adhesive layer 154-2 is disposed on the inner side of the reflective layer 154-1 adjacent to the end of the reflective layer 154-1, the peeling of the reflective layer 154-1 can be fundamentally prevented.

According to the embodiment, since the reflective layer 154-1 is disposed not only on the lower side but also on the lateral part of the light-emitting layer 150a, the area of the reflective layer 154-1 may increase. Thus, it may be more affected by the DEP force, so that the assembly rate can be improved.

According to the embodiment, as illustrated in FIGS. 8 and 10, since the adhesive layer 154-2 is a transparent conductor and has a thickness t1 of 20 nm or less, the light reflectivity is excellent, so that the light emission efficiency and the light luminance can be improved.

According to the embodiment, as illustrated in FIGS. 33 and 34, since the adhesive layer 154-2 having a resistance greater than that of the reflective layer 154-1 is disposed on the lower side of the light-emitting layer 150a, the driving current of the light-emitting layer 150a may flow more to the reflective layer 154-1 on the lateral part of the light-emitting layer 150a than to the adhesive layer 154-2 on the lower side of the light-emitting layer 150a. Accordingly, the amount of light generated in the active layer 152 may increase due to the dispersion of the driving current, so that the light emission efficiency and the light luminance can be improved.

According to the embodiment, as illustrated in FIG. 35 and FIG. 36, the adhesive layer 154-2 may be disposed along the edge of the lower surface of the light-emitting layer 150a, so that the contact area between the adhesive layer 154-2 and the light-emitting layer 150a may be reduced, thereby improving the device's driving characteristics and enhancing the light emission efficiency.

According to the embodiment, as illustrated in FIG. 37, the anti-aggregation layer 158 may be disposed to cover a first electrode 154, so that the aggregation of the semiconductor light-emitting elements due to adsorption during self-assembly can be prevented. In addition, since the first electrode 154 is covered by the anti-aggregation layer 158, the peeling of the reflective layer 154-1 of the first electrode 154 can be fundamentally blocked.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 illustrates a state in which a reflective metal is peeled off from a micro-LED.

FIG. 2 illustrates a living room of a house in which a display device according to an embodiment is disposed.

FIG. 3 is a block diagram schematically showing a display device according to an embodiment.

FIG. 4 is a circuit diagram showing an example of a pixel of FIG. 3.

FIG. 5 is an enlarged view of a first panel area in the display device of FIG. 2.

FIG. 6 is an enlarged view of A2 region of FIG. 5.

FIG. 7 is a drawing showing an example in which a light-emitting element according to an embodiment is assembled on a substrate by a self-assembly method.

FIG. 8 is a cross-sectional view illustrating a semiconductor light-emitting element according to a first embodiment.

FIG. 9 illustrates the appearance of light being reflected in a semiconductor light-emitting element according to the first embodiment.

FIG. 10 is a graph illustrating the reflectivity in each of the comparative example and the first to third embodiments.

FIG. 11 shows the luminance in each of the comparative example and the embodiment.

FIGS. 12 to 32 illustrate a manufacturing process of a semiconductor light-emitting element according to the first embodiment.

FIG. 33 is a cross-sectional view illustrating a semiconductor light-emitting element according to a second embodiment.

FIG. 34 illustrates the flow of driving current in a semiconductor light-emitting element according to the second embodiment.

FIG. 35 is a cross-sectional view illustrating a semiconductor light-emitting element according to a third embodiment.

FIG. 36 is a bottom view illustrating a semiconductor light-emitting element according to the third embodiment with the reflective layer and magnetic layer removed.

FIG. 37 is a cross-sectional view illustrating a semiconductor light-emitting element according to a fourth embodiment.

FIGS. 38 and 39 illustrate a manufacturing process of a semiconductor light-emitting element according to the fourth embodiment.

FIG. 40 is a cross-sectional view illustrating a display device according to an embodiment.

FIG. 41 is a cross-sectional view illustrating a backplane substrate according to an embodiment.

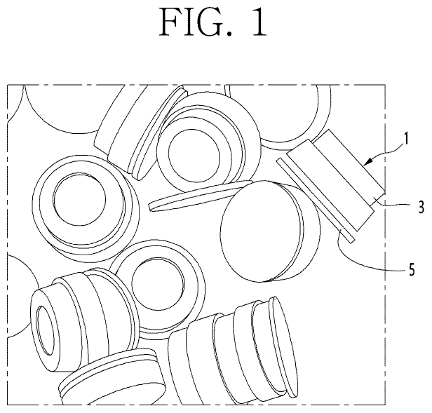

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

The display device described in this specification may comprise a TV, a signage, a mobile terminal such as a mobile phone or a smart phone, a computer display such as a laptop or a desktop, a head-up display (HUD) for an automobile, a backlight unit for a display, a display for extended reality (XR) such as AR, VR, and mixed reality (MR), a light source, etc. However, the configuration according to the embodiments described in this specification may be equally applied to a device capable of displaying, even if it is a new product type developed in the future.

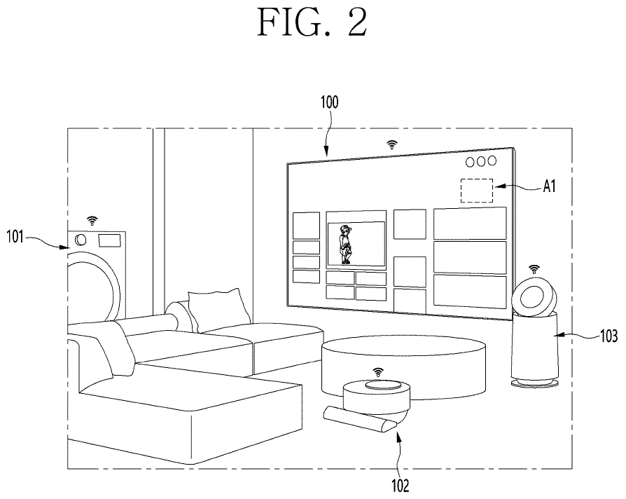

FIG. 2 illustrates a living room of a house in which a display device according to an embodiment is disposed.

Referring to FIG. 2, the display device 100 according to the embodiment may display the status of various electronic products such as a washing machine 101, a robot vacuum cleaner 102, and an air purifier 103, and may communicate with each electronic product based on IoT and control each electronic product based on the user's setting data.

The display device 100 according to the embodiment may comprise a flexible display manufactured on a thin and flexible substrate. The flexible display may be bent or rolled like paper while maintaining the characteristics of a conventional flat display.

In the flexible display, visual information may be implemented by independently controlling the light emission of unit pixels disposed in a matrix form. A unit pixel means a minimum unit for implementing one color. The unit pixel of the flexible display may be implemented by a light-emitting element. In the embodiment, the light-emitting element may be a micro-LED or a nano-LED, but is not limited thereto.

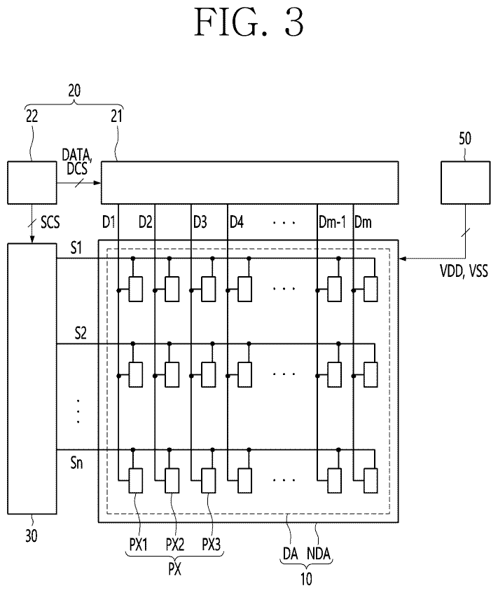

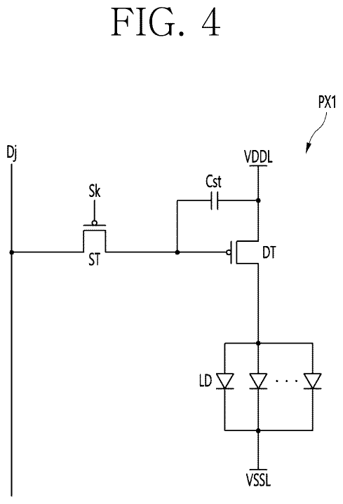

FIG. 3 is a block diagram schematically showing a display device according to an embodiment, and FIG. 4 is a circuit diagram showing an example of a pixel of FIG. 3.

Referring to FIG. 3 and FIG. 4, the display device according to an embodiment may comprise a display panel 10, a driving circuit 20, a scan driving unit 30, and a power supply circuit 50.

The display device 100 of the embodiment may drive a light-emitting element in an active matrix (AM) manner or a passive matrix (PM) manner.

The driving circuit 20 may comprise a data driving unit 21 and a timing control unit 22.

The display panel 10 may be formed in a rectangular shape, but is not limited thereto. That is, the display panel 10 may be formed in a circular or elliptical shape. At least one side of the display panel 10 may be formed to be bent at a predetermined curvature.

The display panel may comprise a display region DA. The display region DA is a region where pixels PX are formed to display an image. The display panel may comprise a non-display region NDA. The non-display region NDA may be a region excluding the display region DA.

As an example, the display region DA and the non-display region NDA may be defined on the same surface. For example, the non-display region NDA may surround the display region DA on the same surface together with the display region DA, but is not limited thereto.

As another example, although not illustrated in the drawing, the display region DA and the non-display region NDA may be defined on different surfaces. For example, the display region DA may be defined on an upper surface of the substrate, and the non-display region NDA may be defined on a lower surface of the substrate. For example, the non-display region NDA may be defined on the entire region or a part of the lower surface of the substrate.

Meanwhile, although the drawing illustrates that the display region DA and the non-display region NDA are separated, the display region DA and the non-display region NDA may not be separated. That is, only the display region DA may exist on the upper surface of the substrate, and the non-display region NDA may not exist. In other words, the entire region of the upper surface of the substrate is the display region DA where the image is displayed, and the bezel area, which is the non-display region NDA, may not exist.

The display panel 10 may comprise data lines (D1 to Dm, where m is an integer greater than or equal to 2), scan lines (S1 to Sn, where n is an integer greater than or equal to 2) intersecting the data lines D1 to Dm, a high-potential voltage line VDDL supplied with a high-potential voltage VDD, a low-potential voltage line VSSL supplied with a low-potential voltage VSS, and pixels PX connected to the data lines D1 to Dm and the scan lines S1 to Sn.

Each of the pixels PX may comprise a first subpixel PX1, a second subpixel PX2, and a third subpixel PX3. The first subpixel PX1 may emit a first color light of a first main wavelength, the second subpixel PX2 may emit a second color light of a second main wavelength, and the third subpixel PX3 may emit a third color light of a third main wavelength. The first color light may be red light, the second color light may be green light, and the third color light may be blue light, but is not limited thereto. In addition, although FIG. 3 exemplifies that each of the pixels PX comprises three subpixels, it is not limited thereto. That is, each of the pixels PX may comprise four or more subpixels.

Each of the first subpixel PX1, the second subpixel PX2, and the third subpixel PX3 may be connected to at least one of the data lines D1 to Dm, at least one of the scan lines S1 to Sn, and a high-potential voltage line VDDL. The first subpixel PX1 may comprise light-emitting elements LD and a plurality of transistors for supplying current to the light-emitting elements LD and at least one capacitor Cst, as illustrated in FIG. 4.

Although not illustrated in the drawing, each of the first subpixel PX1, the second subpixel PX2, and the third subpixel PX3 may comprise only one light-emitting element LD and at least one capacitor Cst.

Each of the light-emitting elements LD may be a semiconductor light-emitting diode comprising a first electrode 154, a plurality of conductivity type semiconductor layers, and a second electrode 155. Here, the first electrode 154 may be an anode electrode, and the second electrode 155 may be a cathode electrode, but is not limited thereto.

The light-emitting element LD may be one of a lateral-type light-emitting element, a flip-chip type light-emitting element, and a vertical-type light-emitting element.

The plurality of transistors may comprise a driving transistor DT for supplying current to the light-emitting elements LD, and a scan transistor ST for supplying a data voltage to the gate electrode of the driving transistor DT, as illustrated in FIG. 4. The driving transistor DT may comprise a gate electrode connected to the source electrode of the scan transistor ST, a source electrode connected to a high-potential voltage line VDDL to which a high-potential voltage VDD is applied, and a drain electrode connected to the first electrodes 154 of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges a difference value between the gate voltage and the source voltage of the driving transistor DT.

The driving transistor DT and the scan transistor ST may be formed as thin film transistors. In addition, in FIG. 4, the driving transistor DT and the scan transistor ST are described as being formed as P-type metal oxide semiconductor field effect transistors (MOSFETs), but the present invention is not limited thereto. The driving transistor DT and the scan transistor ST may also be formed as N-type MOSFETs. In this instance, the positions of the source electrode and the drain electrode of each of the driving transistor DT and the scan transistors ST may be changed.

In addition, in FIG. 4, the first subpixel PX1, the second subpixel PX2, and the third subpixel PX3 each comprise a 2T1C (2 Transistor—1 capacitor) having one driving transistor DT, one scan transistor ST, and one capacitor Cst, but the present invention is not limited thereto. The first subpixel PX1, the second subpixel PX2, and the third subpixel PX3 each may comprise a plurality of scan transistors ST and a plurality of capacitors Cst.

Since the second subpixel PX2 and the third subpixel PX3 may be expressed by substantially the same circuit diagram as the first subpixel PX1, a detailed description thereof will be omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts digital video data DATA into analog data voltages according to the source control signal DCS and supplies the same to data lines D1 to Dm of the display panel 10.

The timing control unit 22 receives digital video data DATA and timing signals from a host system. The host system may be an application processor of a smartphone or tablet PC, a monitor, a system-on-chip of a TV, etc.

The timing control unit 22 generates control signals for controlling the operation timing of the data driving unit 21 and the scan driving unit 30. The control signals may comprise a source control signal DCS for controlling the operation timing of the data driving unit 21 and a scan control signal SCS for controlling the operation timing of the scan driving unit 30.

The driving circuit 20 may be disposed in a non-display region NDA provided on one side of the display panel 10. The driving circuit 20 may be formed as an integrated circuit (IC) and may be mounted on the display panel 10 in a chip on glass (COG) manner, a chip on plastic (COP) manner, or an ultrasonic bonding manner, but the present invention is not limited thereto. For example, the driving circuit 20 may be mounted on a circuit board (not illustrated) other than the display panel 10.

The data driving unit 21 may be mounted on the display panel 10 in a chip on glass (COG) manner, a chip on plastic (COP) manner, or an ultrasonic bonding manner, and the timing control unit 22 may be mounted on a circuit board.

The scan driving unit 30 receives a scan control signal SCS from the timing control unit 22. The scan driving unit 30 generates scan signals according to the scan control signal SCS and supplies them to the scan lines SI to Sn of the display panel 10. The scan driving unit 30 may comprise a plurality of transistors and may be formed in a non-display region NDA of the display panel 10. Alternatively, the scan driving unit 30 may be formed as an integrated circuit, in which case it may be mounted on a gate flexible film attached to the other side of the display panel 10.

The power supply circuit 50 may generate voltages required for driving the display panel 10 from a main power applied from a system board and supply them to the display panel 10. For example, the power supply circuit 50 may generate a high-potential voltage VDD and a low-potential voltage VSS for driving the light-emitting elements LD of the display panel 10 from the main power supply and supply them to the high-potential voltage line VDDL and the low-potential voltage line VSSL of the display panel 10. In addition, the power supply circuit 50 may generate and supply driving voltages for driving the driving circuit 20 and the scan driving unit 30 from the main power supply.

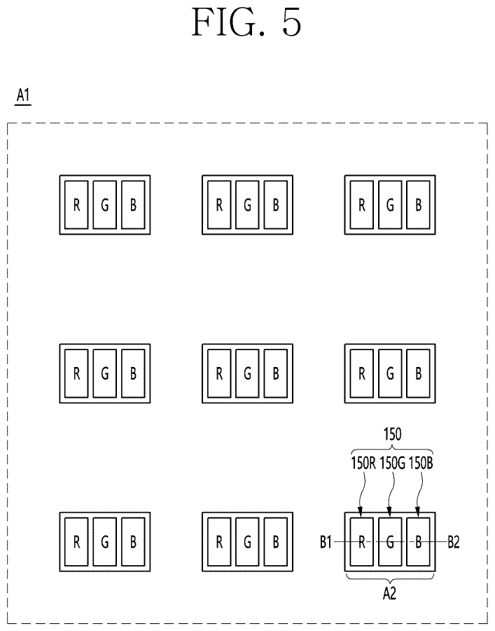

FIG. 5 is an enlarged view of the first panel area in the display device of FIG. 3.

Referring to FIG. 5, the display device 100 of the embodiment may be manufactured by mechanically and electrically connecting a plurality of panel areas such as the first panel area A1 by tiling.

The first panel area A1 may comprise a plurality of semiconductor light-emitting elements 150 disposed for each unit pixel (PX of FIG. 3).

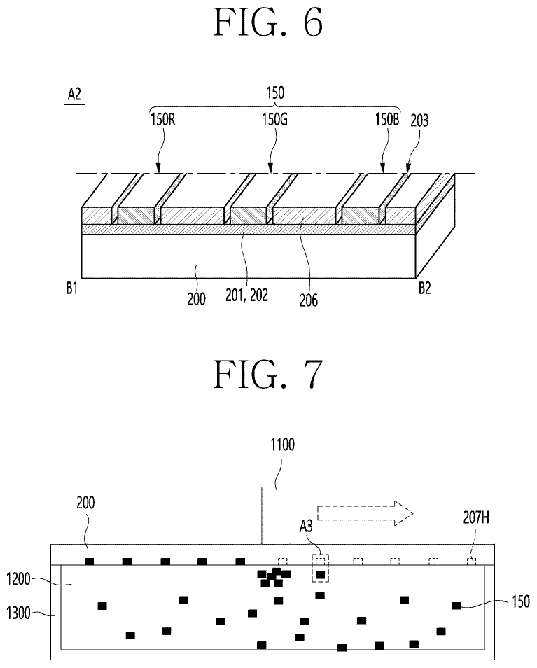

FIG. 6 is an enlarged view of A2 region of FIG. 5.

Referring to FIG. 6, the display device 100 of the embodiment may comprise a substrate 200, assembly wirings 201 and 202, an insulating layer 206, and a plurality of semiconductor light-emitting elements 150. More components may be included.

The assembly wiring may comprise a first assembly wiring 201 and a second assembly wiring 202 that are spaced apart from each other. The first assembly wiring 201 and the second assembly wiring 202 may be provided to generate a dielectrophoretic force (DEP force) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise, but is not limited to, a red semiconductor light-emitting element 150R, a green semiconductor light-emitting element 150G, and a blue semiconductor light-emitting element 150B to form a unit pixel, respectively, and may also comprise a red phosphor and a green phosphor to implement red and green, respectively.

The substrate 200 may be a support member that supports components disposed on the substrate 200, or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET). In addition, the substrate 200 may be a transparent material, but is not limited thereto. The substrate 200 may function as a support substrate in the display panel, and may also function as an assembly substrate when self-assembling the light-emitting element.

The substrate 200 may be a backplane substrate equipped with circuits, such as transistors ST and DT, capacitors Cst, and signal wiring, within the subpixels PX1, PX2, and PX3 illustrated in FIGS. 3 and 4, but is not limited thereto.

The insulating layer 206 may comprise an organic material having insulation and flexibility, such as polyimide, PAC, PEN, PET, polymer, or an inorganic material such as silicon oxide (SiO₂) or silicon nitride (SiNx), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be an anisotropic conductive film (ACF) or a conductive adhesive layer such as an anisotropic conductive medium, a solution containing conductive particles, etc. The conductive adhesive layer may be a layer that is electrically conductive in a vertical direction relative to the thickness, but electrically insulating in a horizontal direction relative to the thickness.

The insulating layer 206 may comprise an assembly hole 203 for inserting the semiconductor light-emitting element 150. Therefore, during self-assembly, the semiconductor light-emitting element 150 may be easily inserted into the assembly hole 203 of the insulating layer 206. The assembly hole 203 may be named an insertion hole, a fixing hole, an alignment hole, etc. The assembly hole 203 may also be named a hole.

The assembly hole 203 may be named a hole, a groove, a recess, a pocket, etc.

The assembly hole 203 may vary depending on the shape of the semiconductor light-emitting element 150. For example, the red semiconductor light-emitting element, the green semiconductor light-emitting element, and the blue semiconductor light-emitting element each have different shapes, and may have an assembly hole 203 having a shape corresponding to the shape of each of these semiconductor light-emitting elements. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first elliptical shape having a first minor axis and a second major axis, and the blue semiconductor light-emitting element may have a second elliptical shape having a second minor axis and a second major axis, but is not limited thereto. The second major axis of the elliptical shape of the blue semiconductor light-emitting element may be greater than the first major axis of the elliptical shape of the green semiconductor light-emitting element, and the second minor axis of the elliptical shape of the blue semiconductor light-emitting element may be smaller than the first minor axis of the elliptical shape of the green semiconductor light-emitting element.

Meanwhile, the method of mounting the semiconductor light-emitting element 150 on the substrate 200 may comprise, for example, a self-assembly method (FIG. 7) and a transfer method.

FIG. 7 is a drawing showing an example of assembling a light-emitting element according to an embodiment on a substrate by a self-assembly method.

Based on FIG. 7, an example of assembling a semiconductor light-emitting element according to an embodiment on a display panel by a self-assembly method using an electromagnetic field will be described.

The assembly substrate 200 described below may also function as a panel substrate in a display device after assembling the light-emitting element, but the embodiment is not limited thereto.

Referring to FIG. 7, the semiconductor light-emitting element 150 may be put into a chamber 1300 filled with a fluid 1200, and the semiconductor light-emitting element 150 may move to the assembly substrate 200 by a magnetic field generated from the assembly device 1100. At this time, the semiconductor light-emitting element 150 adjacent to the assembly hole 207H of the assembly substrate 200 may be assembled into the assembly hole 207H by the DEP force due to the electric field of the assembly wirings. The fluid 1200 may be water such as ultrapure water, but is not limited thereto. The chamber may be named a tank, a container, a vessel, etc.

After the semiconductor light-emitting element 150 is put into the chamber 1300, the assembly substrate 200 may be disposed on the chamber 1300. According to an embodiment, the assembly substrate 200 may be put into the chamber 1300.

Meanwhile, the first assembly wiring 201 and the second assembly wiring 202 form an electric field when an AC voltage is applied, and the semiconductor light-emitting element 150 put into the assembly hole 207H may be fixed by the DEP force caused by the electric field. The gap between the first assembly wiring 201 and the second assembly wiring 202 may be smaller than the width of the semiconductor light-emitting element 150 and the width of the assembly hole 207H, and the assembly position of the semiconductor light-emitting element 150 may be fixed more precisely using the electric field.

An insulating layer 215 is formed on the first assembly wiring 201 and the second assembly wiring 202 to protect the first assembly wiring 201 and the second assembly wiring 202 from the fluid 1200 and prevent leakage of current flowing in the first assembly wiring 201 and the second assembly wiring 202. For example, the insulating layer 215 may be formed as a single layer or multiple layers of an inorganic insulator such as silica or alumina or an organic insulator. The insulating layer 215 may have a minimum thickness to prevent damage to the first assembly wiring 201 and the second assembly wiring 202 during assembly of the semiconductor light-emitting element 150, and may have a maximum thickness to stably assemble the semiconductor light-emitting element 150.

A partition wall 207 may be formed on the upper part of the insulating layer 215. A part of the partition wall 207 may be positioned on the upper part of the first assembly wiring 201 and the second assembly wiring 202, and the remaining regions may positioned on the upper part of the assembly substrate 200.

Meanwhile, when manufacturing the assembly substrate 200, a part of the partition wall formed at the upper part of the insulating layer 215 may be removed, thereby forming assembly holes 207H in which each of the semiconductor light-emitting elements 150 is coupled and assembled to the assembly substrate 200.

The assembly substrate 200 has assembly holes 207H formed in which the semiconductor light-emitting elements 150 are coupled, and a surface on which the assembly holes 207H are formed may be in contact with the fluid 1200. The assembly holes 207H may guide the exact assembly positions of the semiconductor light-emitting elements 150.

Meanwhile, the assembly holes 207H may have a shape and size corresponding to the shape of the semiconductor light-emitting elements 150 to be assembled at the corresponding positions. Accordingly, it is possible to prevent another semiconductor light-emitting element from being assembled in the assembly hole 207H or a plurality of semiconductor light-emitting elements from being assembled.

Referring again to FIG. 7, after the assembly substrate 200 is disposed in the chamber, the assembly device 1100 applying a magnetic field may move along the assembly substrate 200. The assembly device 1100 may be a permanent magnet or an electromagnet.

The assembly device 1100 may move in contact with the assembly substrate 200 in order to maximize a region affected by the magnetic field within the fluid 1200. Depending on the embodiment, the assembly device 1100 may comprise a plurality of magnetic substances or may comprise a magnetic substance having a size corresponding to that of the assembly substrate 200. In this instance, the movement distance of the assembly device 1100 may be limited within a predetermined range.

The semiconductor light-emitting element 150 in the chamber 1300 may move toward the assembly device 1100 and the assembly substrate 200 by the magnetic field generated by the assembly device 1100.

The semiconductor light-emitting element 150 may be fixed by entering the assembly hole 207H by the DEP force formed by the electric field between the assembly wirings 201 and 202 while moving toward the assembly device 1100.

By the self-assembly method using the electromagnetic field described above, the time required for each semiconductor light-emitting element to be assembled on the substrate may be drastically shortened, so that a large-area high-pixel display may be implemented more quickly and economically.

Hereinafter, various embodiments for solving the above-described problem will be described with reference to FIGS. 8 to 41. The omitted description below may be easily understood from the description described above in relation to FIGS. 2 to 7 and the corresponding drawings.

The semiconductor light-emitting element described below may have a size of less than a micrometer.

In addition, the semiconductor light-emitting element described below may be a vertical-type semiconductor light-emitting element in which current flows vertically.

### First Embodiment

FIG. 8 is a cross-sectional view illustrating a semiconductor light-emitting element according to a first embodiment.

Referring to FIG. 8, the semiconductor light-emitting element 150A according to the first embodiment may comprise a light-emitting layer 150a, a passivation layer 157, a first electrode 154, and a second electrode 155.

The light-emitting layer 150a may emit light of a specific color. The specific color light may be determined by a semiconductor material of the light-emitting layer 150a. The specific color light may be, for example, red light, green light, or blue light. Hereinafter, the light-emitting layer 150a will be described as emitting red light, but the light-emitting layer 150a of the embodiment may also emit green light or blue light.

The light-emitting layer 150a may comprise a plurality of semiconductor layers. For example, the light-emitting layer 150a may comprise at least one first conductivity type semiconductor layer 151, an active layer 152, and at least one second conductivity type semiconductor layer 153. The active layer 152 may be disposed on the first conductivity type semiconductor layer 151, and the second conductivity type semiconductor layer 153 may be disposed on the active layer 152. The first conductivity type semiconductor layer 151 may comprise an n-type dopant, and the second conductivity type semiconductor layer 153 may comprise a p-type dopant, but is not limited thereto.

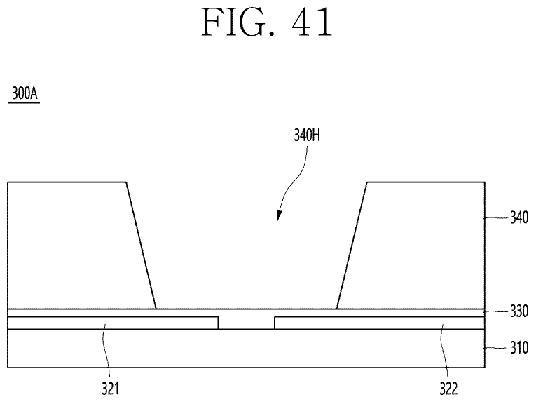

The passivation layer 157 may be made of a material having excellent insulating properties, and may protect the light-emitting layer 150a and prevent leakage current flowing on a lateral part of the light-emitting layer 150a. In addition, the passivation layer 157 may cause a repulsive force with respect the DEP force during self-assembly, so that the first electrode 154 of the semiconductor light-emitting element 150A may be correctly assembled by facing a bottom surface of the assembly hole 340H on a backplane substrate (300A of FIG. 41).

The passivation layer 157 may surround the lateral part of the light-emitting layer 150a. The passivation layer 157 may be disposed along the perimeter of the lateral part of the light-emitting layer 150a. The passivation layer 157 may be disposed on an upper side of the second electrode 155.

Meanwhile, the passivation layer 157 may not be disposed on a lower side of the first electrode 154. As will be described later, the passivation layer 157 and the first electrode 154 may be affected by the DEP force. For example, the first electrode 154 may be subject to an attractive force and the passivation layer 157 may be subject to a repulsive force with respect to the DEP force. Accordingly, when the DEP force is formed in the assembly hole 340H of the backplane substrate 300A and the semiconductor light-emitting element 150A is positioned in the assembly hole 340H, the first electrode 154 of the semiconductor light-emitting element 150A may be pulled and the passivation layer 157 may be pushed by the DEP force formed in the assembly hole 340H, so that the first electrode 154 of the semiconductor light-emitting element 150A may be assembled facing the bottom surface of the assembly hole 340H.

The assembly of the first electrode 154 of the semiconductor light-emitting element 150A facing the bottom surface of the assembly hole 340H may be defined as correct assembly, and the assembly of the passivation layer 157 on the second electrode 155 of the semiconductor light-emitting element 150A facing the bottom surface of the assembly hole 340H may be defined as incorrect assembly. In this instance, when the semiconductor light-emitting element 150A is correctly assembled, the semiconductor light-emitting element 150A emits light normally, but when the semiconductor light-emitting element 150A is incorrectly assembled, the semiconductor light-emitting element 150A does not emit light, resulting in a lighting defect. In the embodiment, the passivation layer 157 may cover the remaining region except for the first electrode 154, i.e., the light-emitting portion and/or the second electrode 155, so that the first electrode 154 of the semiconductor light-emitting element 150A may be correctly assembled in the assembly hole 340H, thereby preventing the lighting defect.

The first electrode 154 may be disposed under the light-emitting layer 150a. The first electrode 154 may be a cathode electrode and may have a multilayer structure comprising a plurality of layers.

The second electrode 155 may be disposed on the light-emitting layer 150a. The second electrode 155 may be an anode electrode and may have a multilayer structure comprising one layer or a plurality of layers. The second electrode 155 may be in contact with an upper surface of the second conductivity type semiconductor layer 153 of the light-emitting layer 150a, but is not limited thereto. Although not illustrated, a size of the second electrode 155 may be smaller than a size of the light-emitting layer 150a. The second electrode 155 may comprise ITO, IZO, etc., as a transparent conductor so that light from the active layer 152 may be emitted forward.

Hereinafter, the first electrode 154 will be described in more detail.

The first electrode 154 may comprise a reflective layer 154-1, an adhesive layer 154-2, and a magnetic layer 154-3. The first electrode 154 may comprise more layers than these.

The reflective layer 154-1 may be disposed under the light-emitting layer 150a. For example, the reflective layer 154-1 may be disposed under the first conductivity type semiconductor layer 151. The reflective layer 154-1 may comprise a metal having excellent reflectivity, such as Al, Ag, APC (Ag—Pd—Cu alloy), etc.

Although not illustrated, an ohmic contact layer may be disposed under the first conductivity type semiconductor layer 151. For example, a part of the ohmic contact layer may be in contact with a first region of the first conductivity type semiconductor layer 151, and a part of the reflective layer 154-1 may be in contact with a second region of the first conductivity type semiconductor layer 151, but is not limited thereto. As will be described later, as illustrated in FIG. 40, when the first electrode 154 on a lateral part of the first electrode 154, that is, the lateral part of the light-emitting layer 150a, is connected to a connecting electrode 370, the ohmic contact layer may be in contact with a side surface of the first conductivity type semiconductor layer 151, and the reflective layer 154-1 may be in contact with a lower surface of the first conductivity type semiconductor layer 151. In this instance, a part of the reflective layer 154-1 may horizontally overlap with the ohmic contact layer. That is, the ohmic contact layer may be disposed between a side surface of the reflective layer 154-1 and a side surface of the first conductivity type semiconductor layer 151. Accordingly, since the driving current flowing in the light-emitting layer 150a flows to the connecting electrode 370 through the ohmic contact layer on the side surface of the first conductivity type semiconductor layer 151, the electrical characteristics of the semiconductor light-emitting element 150A can be improved.

In the embodiment, the adhesive layer 154-2 may be disposed between the light-emitting layer 150a and the reflective layer 154-1 to strengthen the adhesive strength of the reflective layer 154-1 and prevent the peeling of the reflective layer 154-1.

The adhesive layer 154-2 may be a material with excellent adhesive strength. The adhesive strength may be a material with excellent light transmittance. For example, the adhesive layer 154-2 may comprise a transparent conductor, such as ITO, IZO, etc.

Meanwhile, the reflective layer 154-1 may comprise a first reflective layer 154-11 and a second reflective layer 154-12. The first reflective layer 154-11 may be disposed on the side surface of the light-emitting layer 150a. The first reflective layer 154-11 may be disposed on the side surface of the first conductivity type semiconductor layer 151. The first reflective layer 154-11 may be disposed along the perimeter of the side surface of the first conductivity type semiconductor layer 151. The second reflective layer 154-12 may be disposed on the lower surface of the light-emitting layer 150a. The second reflective layer 154-12 may be disposed on the lower surface of the first conductivity type semiconductor layer 151. In this instance, the first reflective layer 154-11 may be formed by extending the second reflective layer 154-12 on the lower surface of the light-emitting layer 150a to the side surface of the light-emitting layer 150a. Accordingly, the end of the reflective layer 154-1 may be the uppermost side of the first reflective layer 154-11.

In the embodiment, the adhesive layer 154-2 may be disposed corresponding to the entire region of the reflective layer 154-1, or may be partially disposed on a part of the reflective layer 154-1, for example, the first reflective layer 154-11 or the second reflective layer 154-12.

When the second reflective layer 154-12 on the lower surface of the light-emitting layer 150a is formed to extend to the side surface of the light-emitting layer 150a, the end of the reflective layer 154-1 may be the uppermost side of the first reflective layer 154-11. It is easy for poor adhesion to occur between the inner surface of the first reflective layer 154-11 adjacent to the uppermost side of the first reflective layer 154-11, where the reflective layer 154-1 is the end, and the side surface of the first conductivity type semiconductor layer 151.

According to an embodiment, as illustrated in FIG. 8, the adhesive layer 154-2 may be disposed between the light-emitting layer 150a and the first reflective layer 154-11. The adhesive layer 154-2 may be disposed between the side surface of the first conductivity type semiconductor layer 151 and the first reflective layer 154-11. Therefore, since the inner surface of the first reflection layer 154-11 adjacent to the end of the first reflection layer 154-11, which is prone to adhesion defect by the adhesive layer 154-2, is strongly adhered to the side surface of the first conductivity type semiconductor layer 151, the peeling defect of the reflection layer 154-1 can be prevented.

Meanwhile, as illustrated in FIG. 9, light generated in the active layer 152 and propagated downward is directly reflected forward by the reflection layer 154-1 or indirectly reflected forward by the reflection layer 154-1 via the adhesive layer 154-2 made of a transparent conductor, so that the light emission efficiency can be improved and the luminance of the semiconductor light-emitting element 150A can be improved.

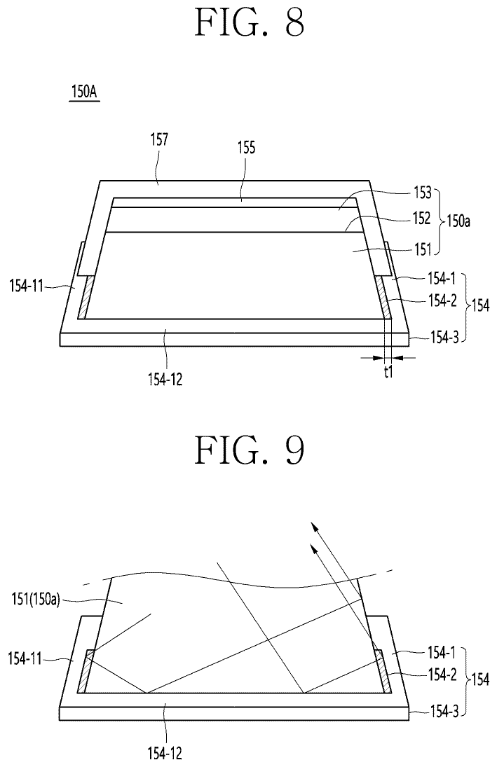

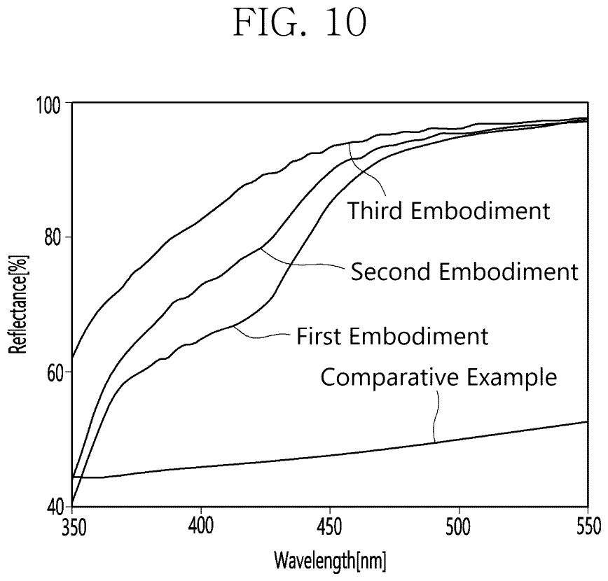

FIG. 10 is a graph illustrating the reflectivity in each of the comparative example and the first to third embodiments. The reflectivity illustrated in FIG. 10 was measured at a wavelength of 450 nm.

The comparative example is a case where the reflective layer 154-1 and the adhesive layer 154-2 are not provided, and the first to third embodiments are cases where the reflective layer 154-1 and the adhesive layer 154-2 are provided, respectively. The thickness t1 of the adhesive layer 154-2 in the first embodiment may be 15 nm, the thickness t1 of the adhesive layer 154-2 in the second embodiment may be 10 nm, and the thickness t1 of the adhesive layer 154-2 in the third embodiment may be 5 nm.

As illustrated in FIG. 10, it may be seen that the reflectivity of each of the first to third embodiments is significantly higher than that of the comparative example. In particular, it may be seen that the reflectivity increases as the thickness t1 of the adhesive layer 154-2 decreases. As the thickness t1 of the adhesive layer 154-2 decreases, the light transmittance increases, and the amount of light absorbed by the adhesive layer 154-2 decreases due to the increase in the light transmittance, so that the reflectivity can increase.

In the embodiment, the adhesive layer 154-2 may have a thickness t1 of 20 nm or less. Therefore, in the embodiment, even if the adhesive layer 154-2 is disposed between the reflective layer 154-1 and the light-emitting layer 150a, a reflectivity of 80% or more may be implemented by setting the thickness t1 of the adhesive layer 154-2 to 20 nm or less, so that the light emission efficiency and the light luminance can be improved.

FIG. 11 shows the luminance in each of the comparative example and the embodiment.

The comparative example is a case where the reflective layer 154-1 is not provided, and the embodiment is a case where the reflective layer 154-1 is provided.

As illustrated in FIG. 11, it may be seen that the embodiment has a wider emission region and higher light luminance than the comparative example.

Meanwhile, since the adhesive layer 154-2 has a hydrophilic surface, the adhesive performance can be further improved. Plasma treatment may be performed so that the adhesive layer 154-2 has a hydrophilic surface, which will be described in detail later.

Referring again to FIG. 8, a part of the reflective layer 154-1 may be disposed on the passivation layer 157. That is, the first reflective layer 154-11 may be formed by extending from the second reflective layer 154-12 on the lower surface of the first conductivity type semiconductor layer 151 to the side surface of the first conductivity type semiconductor layer 151. In addition, a part of the first reflective layer 154-11 may be disposed on the passivation layer 157 on the side surface of the first conductivity type semiconductor layer 151. A part of the first reflective layer 154-11 may cover the passivation layer 157. The first reflective layer 154-11 and the passivation layer 157 may be horizontally overlapped.

In this way, by disposing a part of the reflective layer 154-1 on the passivation layer 157, the peeling defect of the reflective layer 154-1 can be prevented. That is, since the adhesion between the reflection layer 154-1 and the passivation layer 157 is excellent, even if the adhesion between the reflection layer 154-1 and the first semiconductor light-emitting element 150A is poor, the peeling defect of the reflection layer 154-1 can be prevented by the end region of the reflection layer 154-1 being adhered to the passivation layer 157.

Meanwhile, the magnetic layer 154-3 may be disposed on the reflection layer 154-1. The magnetic layer 154-3 may be magnetized by a magnet. For example, the magnetic layer 154-3 is a material having excellent magnetization and may comprise Ni, Co, Fe, etc. At this time, the magnetization strength of the magnetic layer 154-3 may be determined by the area or thickness of the magnetic layer 154-3.

The magnetic layer 154-3 may be disposed on the lower surface of the light-emitting layer 150a. Although not illustrated, the magnetic layer 154-3 may be disposed on the reflective layer 154-1, i.e., the first reflective layer 154-11, on the lateral part of the light-emitting layer 150a. In this way, the magnetic layer 154-3 may be disposed not only on the lower surface of the light-emitting layer 150a but also on the lateral part of the light-emitting layer 150a, so that the arrangement area thereof can be increased. Accordingly, the intensity of magnetization for the magnet may also be increased, so that the response speed and movement speed of the semiconductor light-emitting element 150A for the movement of the magnet during self-assembly can be increased, so that the assembly rate of the semiconductor light-emitting element 150A can be improved.

Meanwhile, although not illustrated, the semiconductor light-emitting element 150A may have a multi-stage structure. The multi-stage structure may be formed, for example, in the first conductive semiconductor light-emitting element 150A. For example, the multi-stage structure may be formed by having different areas or widths in the first conductivity type semiconductor layer 151. For example, the width of the lower side and the width of the upper side of the first conductivity type semiconductor layer 151 may be different. In this instance, a step may occur between the upper side of the first conductivity type semiconductor layer 151 and the lower side of the first conductivity type semiconductor layer 151. That is, the upper surface of the edge region of the lower side of the first conductivity type semiconductor layer 151 is not overlapped by the upper side of the first conductivity type semiconductor layer 151, and thus may be exposed to the outside.

Due to the multi-stage structure of the semiconductor light-emitting element 150A, assembly defect can be prevented during self-assembly. That is, due to the multi-stage structure of the semiconductor light-emitting element 150A, the semiconductor light-emitting element 150A may move to the correct position without shaking or flipping up and down significantly during self-assembly, thereby preventing assembly defect. Since assembly defect is prevented, lighting defect can also be prevented.

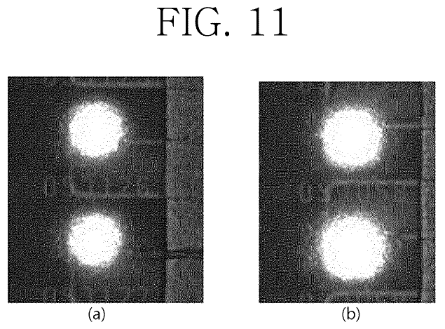

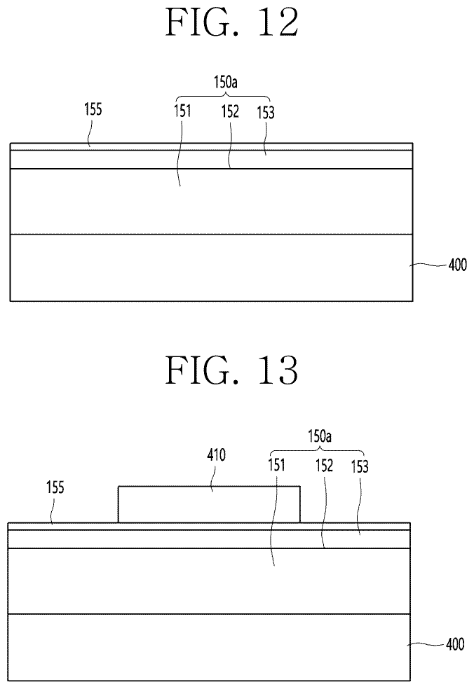

FIGS. 12 to 32 illustrate a manufacturing process of a semiconductor light-emitting element according to the first embodiment.

As illustrated in FIG. 12, a light-emitting layer 150a may be deposited on a growth substrate 400. The growth substrate 400 may be formed of sapphire, GaN, glass, silicon, ceramic, etc. The light-emitting layer 150a may comprise at least one first conductivity type semiconductor layer 151, an active layer 152, and at least one second conductivity type semiconductor layer 153. The first conductivity type semiconductor layer 151 may comprise an n-type dopant, and the second conductivity type semiconductor layer 153 may comprise a p-type dopant.

A second electrode 155 may be formed on the light-emitting layer 150a, i.e., the second conductivity type semiconductor layer 153. The second electrode 155 may comprise a transparent conductive material, such as ITO or IZO, since light of the active layer 152 must be emitted forward.

As illustrated in FIG. 13, a PR pattern 410 may be formed on the second electrode 155. That is, a photosensitive film may be formed on the second electrode 155, and the PR pattern 410 may be formed through an exposure and development process. The PR pattern 410 may have a size corresponding to a size of the chip.

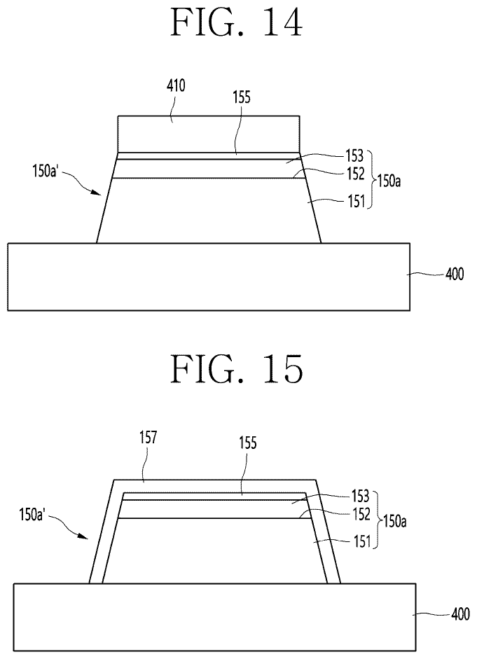

As illustrated in FIG. 14, an etching process may be performed using the PR pattern 410 as a mask, so that the second electrode 155 and the light-emitting layer 150a may be removed. Since the PR pattern 410 is used as a mask, the second electrode 155 and the light-emitting layer 150a corresponding to the PR pattern 410 may not be removed. The second electrode 155 and light-emitting layer 150a corresponding to a region where the PR pattern 410 is not provided may be removed. Accordingly, chips 150a′ as many as the number of PR patterns 410 may be formed.

The etching process may be a dry etching process, and may be not vertically etched but obliquely etched, so that a chip 150a′ having a mesa structure may be formed.

As illustrated in FIG. 15, a passivation layer 157 may be formed on the growth substrate 400. Accordingly, a passivation layer 157 may be formed on the chip 150a′. That is, the passivation layer 157 may be formed along the perimeter of a lateral part of the light-emitting layer 150a and on the second electrode 155.

The drawing illustrates that the passivation layer 157 is not formed on an upper surface of the substrate. That is, after the passivation layer 157 is deposited on the entire region of the substrate, the passivation layer 157 on the upper surface of the substrate may be removed, so that the passivation layer 157 may be not formed on the upper surface of the substrate, but may be formed on the chip 150a′.

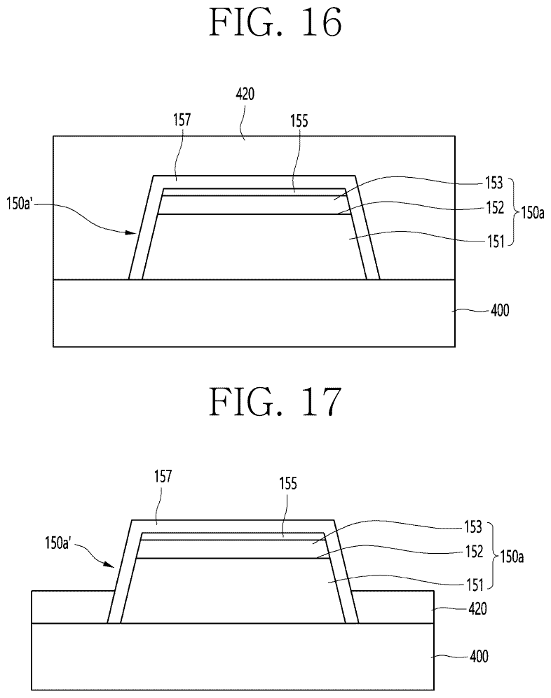

As illustrated in FIG. 16, an organic film 420 may be formed on the growth substrate 400.

As illustrated in FIG. 17, an ashing process may be performed, so that an upper side of the organic film 420 may be removed, and a thickness of the organic film 420 may be reduced. For example, an upper surface of the reduced organic film 420 may be lower than a position of the active layer 152.

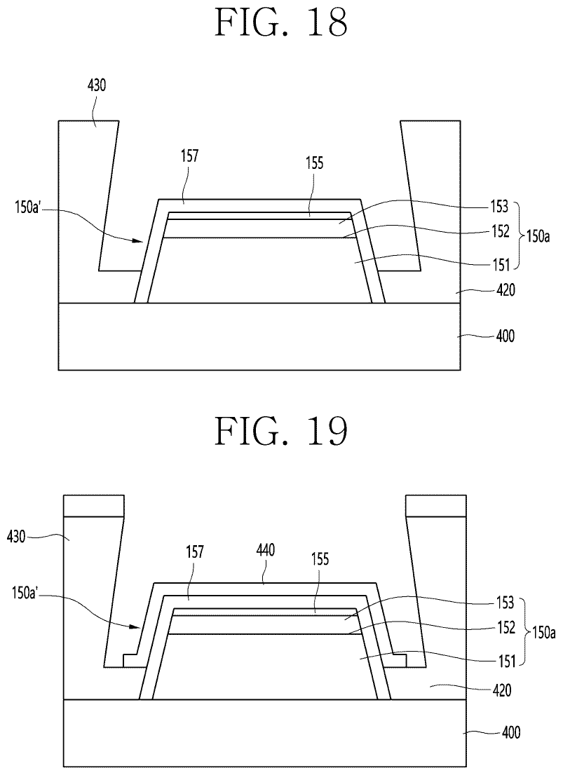

As illustrated in FIG. 18, a PR pattern 430 may be formed on the organic film 420. Both the PR pattern 430 and the organic film 420 may be photosensitive films, and the boundary between the organic film 420 and the PR pattern 430 may not be distinguished.

As illustrated in FIG. 19, a metal film 440 may be deposited on the substrate. The metal film 440 may comprise Cr, Ni, Mo, etc. A thickness of the PR pattern 430 may be large, and an inner side of the PR pattern 430 may have a structure in which the width thereof becomes wider as it goes inward. When the metal film 440 is deposited on the PR pattern 430, the metal film 440 may be deposited on the chip 150a′ and the PR pattern 430. At this time, the metal film 440 on the chip 150a′ may be horizontally spaced from the inner side of the PR pattern 430.

As illustrated in FIG. 20, the metal film 440 on the PR pattern 430 may also be removed together by removing the PR pattern 430 and the organic film 420 through a lift-off process. By removing the organic film 420, the metal film 440 on the chip 150a′ may be spaced from the growth substrate 400 by a thickness of the organic film 420. In other words, the passivation layer 157 corresponding to the thickness of the organic film 420 on the lateral part of the light-emitting layer 150a may be exposed to the outside.

As illustrated in FIG. 21, the exposed passivation layer 157 may be removed through wet etching, so that a side surface of the first conductivity type semiconductor layer 151 corresponding to the removed passivation layer 157 may be exposed to the outside. Since the metal film 440 acts as a mask while wet etching is performed, the passivation layer 157 covered by the metal film 440 may not be removed.

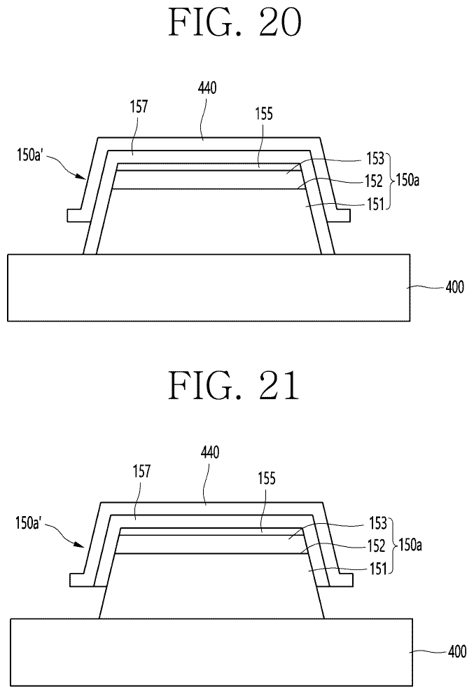

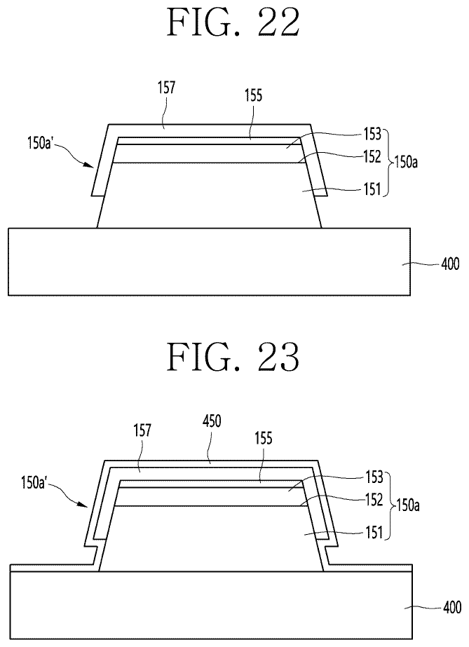

As illustrated in FIG. 22, the passivation layer 157 may be exposed to the outside by removing the metal film 440 through wet etching.

As illustrated in FIG. 23, a conductive film 450 may be deposited on a substrate. The conductive film 450 may comprise a transparent conductive material, such as ITO, IZO, etc. Meanwhile, in order to strengthen the adhesive strength, the surface characteristics of the conductive film 450 may be changed through O2 plasma treatment. Accordingly, since the conductive film 450 has a hydrophilic surface, the reflective layer to be formed later may be more firmly adhered.

Since the conductive film 450 has a hydrophilic surface, the adhesive performance can be further improved. Plasma treatment may be performed so that the conductive film 450 has a hydrophilic surface, which will be described in detail later.

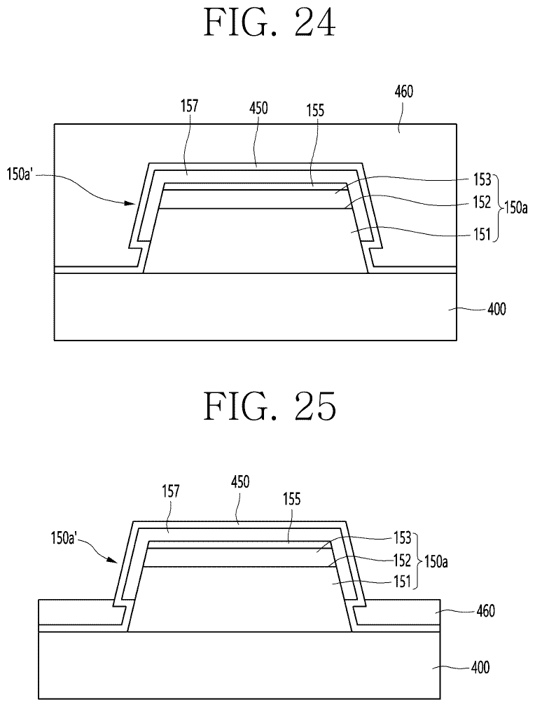

Thereafter, after an organic film 460 is formed on the conductive film 450 (FIG. 24), an upper side of the organic film 460 may be removed through an ashing process to reduce the thickness of the organic film 460 (FIG. 25). At this time, an upper surface of the reduced organic film 460 may be horizontally aligned with the end of the passivation layer 157, but is not limited thereto.

In this way, as the thickness of the organic film 460 is reduced, the conductive film 450 may be exposed to the outside in a region not covered by the organic film 460.

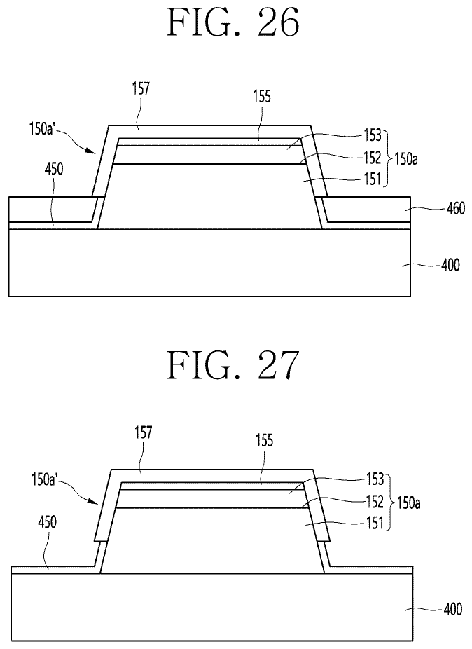

As illustrated in FIG. 26, the exposed conductive film 450 may be removed through wet etching. At this time, since the organic film 460 acts as a mask, the conductive film 450 not exposed by the organic film 460, i.e., the conductive film 450 on the lower side of the first conductivity type semiconductor layer 151, is not removed.

As illustrated in FIG. 27, the organic film 460 may be removed.

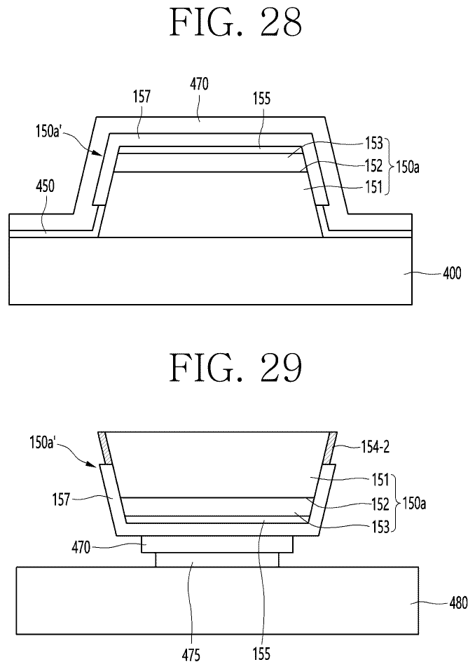

As illustrated in FIG. 28, a sacrificial layer 470 may be formed and patterned on the substrate, so that it may be formed only on the second electrode 155.

As illustrated in FIG. 29, after the chip 150a′ is bonded to a temporary substrate 480 via the adhesive layer 475, the growth substrate 400 may be removed. That is, the growth substrate 400 may be removed through a LLO process. Although not illustrated, after the growth substrate 400 is removed, a cleaning process, a polishing process, a drying process, etc., for removing foreign substances may be performed. In addition, when an undoped layer is formed by being in contact with the growth substrate 400, the undoped layer may be removed through an etching process.

Meanwhile, when the growth substrate 400 is removed, the conductive film 450 remains on the side surface adjacent to the lower surface of the first conductivity type semiconductor layer 151, so that the adhesive layer 475 may be formed.

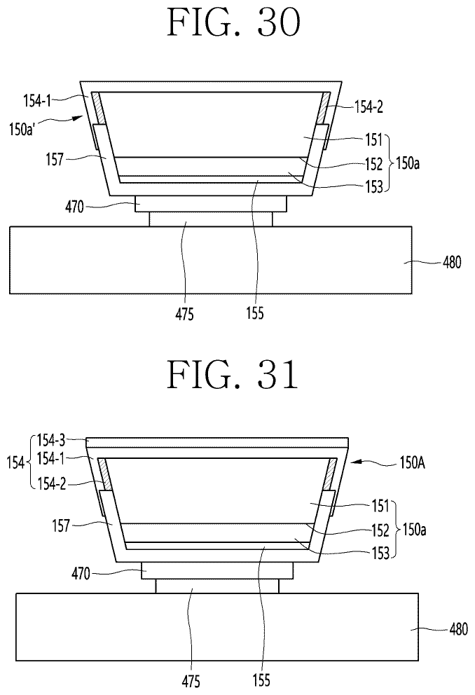

As illustrated in FIG. 30, a reflective layer 154-1 may be deposited on the temporary substrate 480. A reflective metal may be controlled to be deposited at various angles using a sputter equipment. Accordingly, the reflective metal may be formed as the reflective layer 154-1 on a surface of the first conductivity type semiconductor layer 151 and the adhesive layer 475. In this instance, the reflective layer 154-1 may be firmly adhered to the first conductivity type semiconductor layer 151 without being peeled off by the adhesive layer 475.

As illustrated in FIG. 31, a magnetic layer 154-3 may be deposited on the reflective layer 154-1 on the first conductivity type semiconductor layer 151. Although not illustrated, the magnetic layer 154-3 may also be deposited on the reflective layer 154-1 on a side surface of the first conductivity type semiconductor layer 151. Accordingly, a first electrode 154 comprising the adhesive layer 475, the reflective layer 154-1, and the magnetic layer 154-3 may be formed. In addition, a semiconductor light-emitting element 150A composed of a light-emitting layer 150a, a passivation layer 157, a first electrode 154, and a second electrode 155 may be formed.

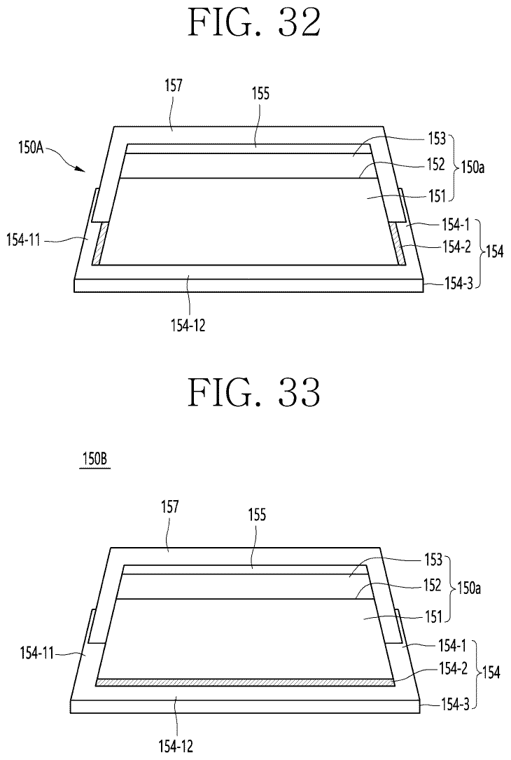

As illustrated in FIG. 32, the semiconductor light-emitting element 150A may be separated from the temporary substrate 480 by removing the sacrificial layer 470 through wet etching.

### Second Embodiment

FIG. 33 is a cross-sectional view illustrating a semiconductor light-emitting element according to a second embodiment.

The second embodiment is the same as the first embodiment except that the adhesive layer 154-2 is disposed on the lower side of the light-emitting layer 150a. In the second embodiment, components having the same shape, structure, and/or function as those of the first embodiment are given the same drawing reference numerals and detailed descriptions are omitted.

Referring to FIG. 33, the semiconductor light-emitting element 150B according to the second embodiment may comprise a light-emitting layer 150a, a passivation layer 157, a first electrode 154, and a second electrode 155.

The first electrode 154 may comprise a reflective layer 154-1, an adhesive layer 154-2, and a magnetic layer 154-3. The first electrode 154 may comprise more layers than these.

The reflective layer 154-1 may comprise a first reflective layer 154-11 and a second reflective layer 154-12. The first reflective layer 154-11 may be disposed on a side surface of the light-emitting layer 150a. The second reflective layer 154-12 may be disposed on a lower surface of the light-emitting layer 150a.

Unlike the first embodiment, in the second embodiment, the adhesive layer 154-2 may be disposed on a lower surface of the light-emitting layer 150a. The adhesive layer 154-2 may be disposed between the lower surface of the light-emitting layer 150a and the reflective layer 154-1 under the light-emitting layer 150a. Since the reflective layer 154-1 is more firmly adhered to the lower surface of the light-emitting layer 150a by the adhesive layer 154-2, the peeling of the reflective layer 154-1 can be prevented.

The adhesive layer 154-2 may comprise a transparent conductor, for example, ITO, IZO, etc. Although the adhesive layer 154-2 is a conductor, it has a greater resistance than the resistance of the reflective layer 154-1. Therefore, the adhesive layer 154-2 suppresses current flow compared to the reflective layer 154-1. That is, the reflective layer 154-1 may allow current to flow more easily than in the adhesive layer 154-2.

As described above, as illustrated in FIG. 40, since a connecting electrode 370 is connected to the reflective layer 154-1 on a lateral part of the light-emitting layer 150a, that is, the first reflective layer 154-11, it is desirable to minimize the current path between the light-emitting layer 150a and the connecting electrode 370.

To this end, in the embodiment, the adhesive layer 154-2 may be disposed between the lower surface of the first conductivity type semiconductor layer 151 and the second reflective layer 154-12, but may not be disposed between the side surface of the first conductivity type semiconductor layer 151 and the first reflective layer 154-11.

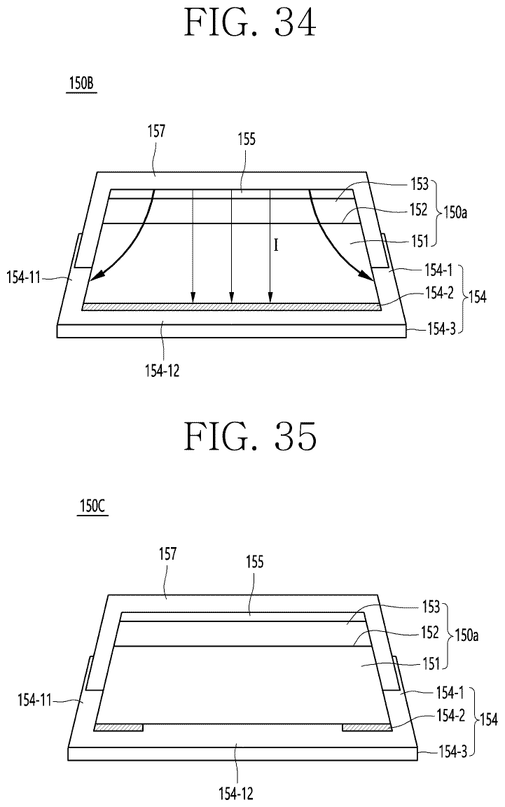

In this instance, as illustrated in FIG. 34, a driving current in the light-emitting layer 150a is more likely to flow from the second electrode 155 toward the first reflective layer 154-11 than from the second electrode 155 toward the second reflective layer 154-12. That is, since the adhesive layer 154-2 having a resistance greater than that of the reflective layer 154-1 is disposed on the lower surface of the first conductivity type semiconductor layer 151, it is difficult for the driving current to flow toward the adhesive layer 154-2.

In contrast, since the adhesive layer 154-2 is not disposed on the side surface of the first conductivity type semiconductor layer 151, and instead, the first reflective layer 154-11 is disposed, the driving current may smoothly flow from the second electrode 155 toward the first reflective layer 154-11. Since the connecting electrode 370 is connected to the first reflective layer 154-11, the current path between the connecting electrode 370 and the light-emitting layer 150a is minimized, so that the driving characteristics of the semiconductor light-emitting element 150B can be improved. That is, sufficient driving current may be obtained even with a lower voltage, so that low-voltage driving is possible, and power consumption may be reduced.

Meanwhile, since the adhesive layer 154-2 is formed of a transparent conductor, the light extraction efficiency can be improved through the current spreading effect.

### Third Embodiment

FIG. 35 is a cross-sectional view illustrating a semiconductor light-emitting element according to a third embodiment.

The third embodiment is the same as the second embodiment except that the adhesive layer 154-2 is disposed along a lower edge region of the light-emitting layer 150a. The third embodiment may be applied to the second embodiment as well. In the third embodiment, components having the same shape, structure, and/or function as those of the second embodiment are given the same drawing reference numerals and detailed descriptions are omitted.

Referring to FIG. 35, the semiconductor light-emitting element 150C according to the third embodiment may comprise a light-emitting layer 150a, a passivation layer 157, a first electrode 154, and a second electrode 155.

The first electrode 154 may comprise a reflective layer 154-1, an adhesive layer 154-2, and a magnetic layer 154-3. The first electrode 154 may comprise more layers than these.

The reflective layer 154-1 may comprise a first reflective layer 154-11 and a second reflective layer 154-12. The first reflective layer 154-11 may be disposed on a side surface of the light-emitting layer 150a. The second reflective layer 154-12 may be disposed on a lower surface of the light-emitting layer 150a.

Unlike the second embodiment, in the third embodiment, the adhesive layer 154-2 may be disposed on a part of the lower surface of the light-emitting layer 150a.

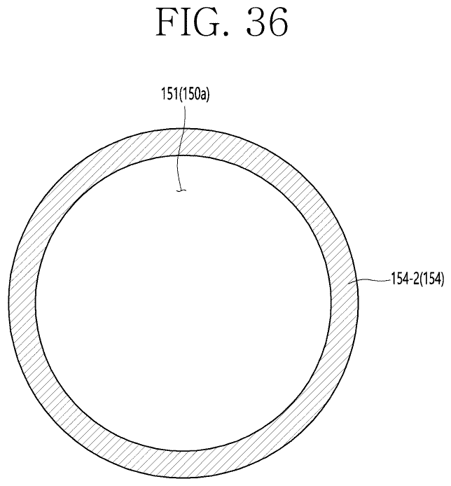

For example, the adhesive layer 154-2 may be disposed along an edge region of the lower surface of the light-emitting layer 150a, as illustrated in FIG. 36. In this instance, the adhesive layer 154-2 may have a ring shape disposed along the edge region of the lower surface of the light-emitting layer 150a, but is not limited thereto.

As described above, the adhesive layer 154-2 may be made of a transparent conductor having relatively high resistance, so a contact area between the adhesive layer 154-2 and the light-emitting layer 150a is better as it decreases. In addition, since the reflectivity of light from the active layer 152 is higher when it is directly reflected by the reflective layer 154-1, rather than being reflected via the adhesive layer 154-2, so that the contact area between the adhesive layer 154-2 and the light-emitting layer 150a is better as it decreases.

Accordingly, in the third embodiment, the adhesive layer 154-2 may be disposed along the edge region of the lower surface of the light-emitting layer 150a, that is, the lower surface of the first conductivity type semiconductor layer 151, so that the contact area between the adhesive layer 154-2 and the light-emitting layer 150a may be reduced, thereby improving the device's driving characteristics and improving the light emission efficiency.

### Fourth Embodiment

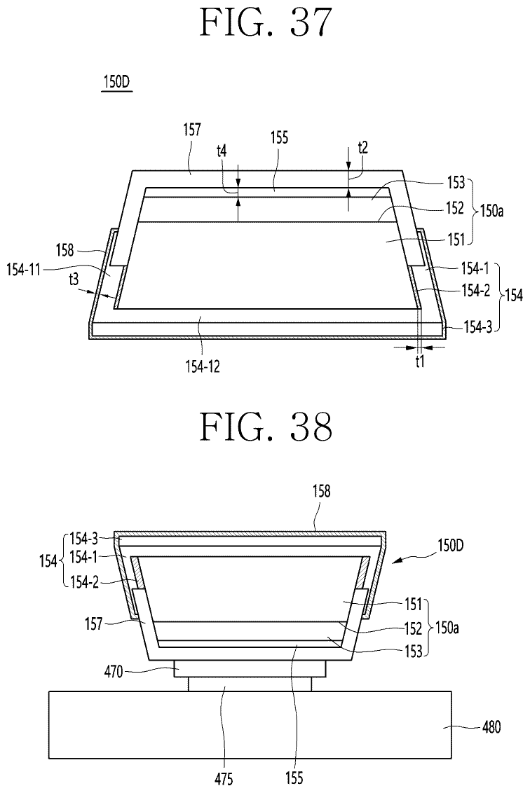

FIG. 37 is a cross-sectional view illustrating a semiconductor light-emitting element according to a fourth embodiment.

The fourth embodiment is the same as the first embodiment except for an anti-aggregation layer 158. The fourth embodiment may be applied equally to the second embodiment or the third embodiment.

In the fourth embodiment, components having the same shape, structure, and/or function as those of the first embodiment are given the same drawing reference numerals and detailed descriptions are omitted.

Referring to FIG. 37, the semiconductor light-emitting element 150D according to the fourth embodiment may comprise a light-emitting layer 150a, a passivation layer 157, a first electrode 154, a second electrode 155, and an anti-aggregation layer 158.

For self-assembly, a plurality of semiconductor light-emitting elements 150D may be dispersed in a fluid, and the plurality of semiconductor light-emitting elements 150D may also move toward the magnet by the movement of the magnet. In this instance, the plurality of semiconductor light-emitting elements 150D may come into contact with or collide with each other. At this time, the metal exposed on the semiconductor light-emitting element 150D, namely the first electrode 154, may cause the semiconductor light-emitting elements 150D to adhere to each other and form an aggregation. Such an aggregation may not be assembled into the assembly hole 340H of the backplane substrate (300A in FIG. 41), and when attached near the assembly hole 340H, it may obstruct other semiconductor light-emitting elements from being assembled into the assembly hole 340H. Once the aggregation is formed, it is not easily separated into individual semiconductor light-emitting elements, so that it is separated through a separate process or discarded after the self-assembly process.

In the fourth embodiment, the anti-aggregation layer 158 may prevent adjacent semiconductor light-emitting elements 150D from being aggregated in the fluid during self-assembly. To this end, the anti-aggregation layer 158 may be disposed under the first electrode 154. The anti-aggregation layer 158 may cover the first electrode 154 so that it is not exposed to the outside. The anti-aggregation layer 158 may cover the reflective layer 154-1 and/or the magnetic layer 154-3 of the first electrode 154. The anti-aggregation layer 158 may be disposed on the lower surface of the light-emitting layer 150a, and may be formed by extending from the lower surface of the light-emitting layer 150a to the side surface of the light-emitting layer 150a. The anti-aggregation layer 158 may be disposed under the magnetic layer 154-3 on the lower surface of the light-emitting layer 150a. The anti-aggregation layer 158 may be disposed on the reflective layer 154-1, i.e., the first reflective layer 154-11, on the side surface of the light-emitting layer 150a. A part of the anti-aggregation layer 158 may be disposed on the passivation layer 157. A part of the anti-aggregation layer 158 may horizontally overlap with the passivation layer 157. A part of the anti-aggregation layer 158 may be in contact with the passivation layer 157.

Meanwhile, the anti-aggregation layer 158 may comprise an insulator. The anti-aggregation layer 158 may comprise an inorganic material. The anti-aggregation layer 158 may comprise, for example, SiO₂.

Meanwhile, when the anti-aggregation layer 158 is thick and also covers the first electrode 154, since the first electrode 154 is not exposed to the outside, the first electrode 154 may no longer be pulled by the DEP force. In this instance, when the semiconductor light-emitting element 150D is positioned in the assembly hole 340H where the DEP force is formed during self-assembly, the first electrode 154 of the semiconductor light-emitting element 150D is not pulled by the DEP force formed in the assembly hole 340H, but is only pushed by the passivation layer 157, so that the semiconductor light-emitting element 150D is no longer assembled in the assembly hole 340H.

To solve this problem, the anti-aggregation layer 158 may have a thin thickness t3 so that an attractive force may be applied to the DEP. For example, the anti-aggregation layer 158 may have a thickness less than or equal to 1/10 of the thickness t2 of the passivation layer 157. For example, when the thickness t2 of the passivation layer 157 is 500 nm, the anti-aggregation layer 158 may have a thickness t3 less than or equal to 50 nm. For example, when the thickness t2 of the passivation layer 157 is 300 nm, the anti-aggregation layer 158 may have a thickness t3 less than or equal to 30 nm. In this way, since the anti-aggregation layer 158 has a very thin thickness t3, an attractive force may be applied against the DEP force, so that the first electrode 154 of the semiconductor light-emitting element 150D may be assembled facing the bottom surface of the assembly hole 340H during self-assembly, thereby improving the assembly rate and preventing assembly defects. In addition, since the first electrode 154 is covered by the anti-aggregation layer 158, the peeling of the reflective layer 154-1 of the first electrode 154 can be fundamentally blocked.

Meanwhile, the thickness t3 of the anti-aggregation layer 158 may be equal to or smaller than the thickness t4 of the second electrode 155.

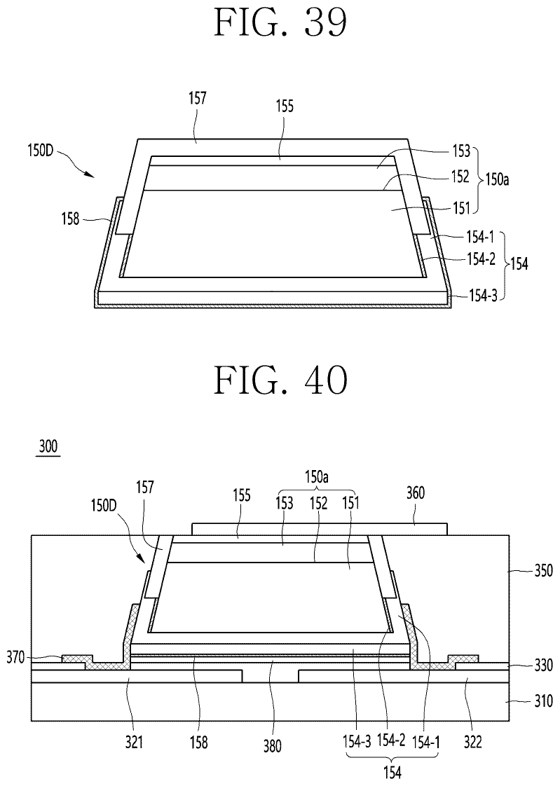

FIG. 38 and FIG. 39 illustrate a manufacturing process of a semiconductor light-emitting element according to the fourth embodiment.

FIG. 38 may be a process that continues from the drawing illustrated in FIG. 31. That is, as illustrated in FIG. 31, a reflective layer 154-1 and a magnetic layer 154-3 may be formed on the light-emitting layer 150a. At this time, the reflective layer 154-1 may be more firmly adhered to the light-emitting layer 150a by the adhesive layer 154-2 formed in advance before the formation of the reflective layer 154-1. The first electrode 154 may be formed by the reflective layer 154-1, the adhesive layer 154-2, and the magnetic layer 154-3.

As illustrated in FIG. 38, an anti-aggregation layer 158 may be formed on the first electrode 154. An inorganic material such as SiO₂ may be deposited on the first electrode 154 to form the anti-aggregation layer 158. The anti-aggregation layer 158 may cover the first electrode 154 so that the first electrode 154 is not exposed to the outside. The anti-aggregation layer 158 may be formed on the reflection layer 154-1, i.e., the first reflection layer 154-11, on the lateral part of the light-emitting layer 150a. At this time, a part of the anti-aggregation layer 158 may be in contact with the passivation layer 157. The anti-aggregation layer 158 may be formed on the magnetic layer 154-3 on the upper side of the light-emitting layer 150a.

As illustrated in FIG. 39, the sacrificial layer 470 may be removed through wet etching, thereby allowing the semiconductor light-emitting element 150D to be separated from the temporary substrate 480.

FIG. 40 is a cross-sectional view illustrating a display device according to an embodiment.

Referring to FIG. 40, the display device 300 according to the embodiment may comprise a backplane substrate 300A, a fixing member 380, a semiconductor light-emitting element 150D, a connecting electrode 370, a second insulating layer 350, and an electrode wiring 360.

The semiconductor light-emitting element 150D may be the semiconductor light-emitting element 150D according to the fourth embodiment, but may also be the semiconductor light-emitting elements 150A to 150C according to the first to third embodiments.

The display device 300 according to the embodiment may be manufactured using the backplane substrate 300A illustrated in FIG. 41. That is, the semiconductor light-emitting element 150D may be assembled into the assembly hole 340H of the backplane substrate 300A using a self-assembly process. Thereafter, after the partition wall 340 on the backplane substrate 300A is removed, the connecting electrode 370, the second insulating layer 350, and the electrode wiring 360 may be formed through a post-process, so that the display device 300 according to the embodiment may be manufactured. Although the drawing illustrates the display device 300 from which the partition wall 340 has been removed, the display device 300 may be provided with the partition wall 340 without being removed.

The backplane substrate 300A may comprise a substrate 310, a first assembly wiring 321, a second assembly wiring 322, a first insulating layer 330, and a partition wall 340.

The substrate 310 is a support substrate for supporting components of the display device 300 according to the embodiment, such as the semiconductor light-emitting element 150D, the connecting electrode 370, the second insulating layer 350, the electrode wiring 360, etc., and may be named a lower substrate or a display substrate. Although not illustrated, an upper substrate may be disposed on the electrode wiring 360, but is not limited thereto.

The first assembly wiring 321 may be disposed on the substrate 310. The second assembly wiring 322 may be disposed on the substrate 310.

For example, the first assembly wiring 321 and the second assembly wiring 322 may be disposed on the same layer. For example, the first and second assembly wirings 321 and 322 may be in contact with an upper surface of the substrate 310, but is not limited thereto. For example, the first assembly wiring 321 and the second assembly wiring 322 may be disposed on the same layer. For example, the first assembly wiring 321 and the second assembly wiring 322 may be disposed parallel to each other. The first assembly wiring 321 and the second assembly wiring 322 may each play a role of assembling the semiconductor light-emitting element 150D into the assembly hole 340H using a self-assembly method. That is, when self-assembling, an electric field may be generated between the first assembly wiring 321 and the second assembly wiring 322 by the voltage supplied to the first assembly wiring 321 and the second assembly wiring 322, and the semiconductor light-emitting element 150D moving by the assembly device (1100 of FIG. 10) may be assembled into the assembly hole 340H by the DEP force formed by the electric field. The assembly hole 340H may have a diameter greater than a diameter of the semiconductor light-emitting element 150D.

The first assembly wiring 321 and the second assembly wiring 322 may each comprise a plurality of metal layers. Although not illustrated, the first assembly wiring 321 and the second assembly wiring 322 may each comprise a main wiring and an auxiliary electrode. The main wiring of each of the first assembly wiring 321 and the second assembly wiring 322 may be disposed long along one direction of the substrate 310. The auxiliary electrode of each of the first assembly wiring 321 and the second assembly wiring 322 may extend from the main wiring toward the assembly hole 340H. The auxiliary electrode may be electrically connected to the main wiring. The main wiring may be disposed on the auxiliary wiring so that a lower surface of the main wiring may be in contact with an upper surface of the auxiliary wiring, but is not limited thereto.

Meanwhile, although not illustrated, the first assembly wiring 321 and the second assembly wiring 322 may be disposed on different layers.

The first insulating layer 330 may be disposed on the first assembly wiring 321 and the second assembly wiring 322. For example, the first insulating layer 330 may be formed of an inorganic material or an organic material. For example, the first insulating layer 330 may be formed of a material having a permittivity related to the DEP force. For example, the higher the permittivity of the first insulating layer 330, the greater the DEP force may be, but is not limited thereto. The first insulating layer 330 may prevent the fluid from directly being in contact with the first assembly wiring 321 or the second assembly wiring 322 and causing corrosion during self-assembly by the assembly hole 340H of the partition wall 340 formed later.

Although the drawing illustrates that the first insulating layer 330 is removed within the assembly hole 340H, the first insulating layer 330 may remain in an unremoved state within the assembly hole 340H in the backplane substrate 300A. The process of removing the first insulating layer 330 within the assembly hole 340H may be performed after the semiconductor light-emitting element 150D is assembled in the assembly hole 340H. The removal of the first insulating layer 330 within the assembly hole 340H may be for electrically connecting the connecting electrode 370 with the first assembly wiring 321 and/or the second assembly wiring 322.

The partition wall 340 may be disposed on the first insulating layer 330. The first insulating layer 330 may have the assembly hole 340H. The assembly hole 340H may be formed in each of the plurality of subpixels PX1, PX2, and PX3 of each of the plurality of pixels PX. That is, it may be formed in one assembly hole 340H per subpixel PX1, PX2, and PX3, but is not limited thereto. For example, the first insulating layer 330 may be exposed within the assembly hole 340H. For example, a bottom surface 158-2 of the assembly hole 340H may be an upper surface of the first insulating layer 330.

The height (or thickness) of the partition wall 340 may be determined by considering the thickness of the semiconductor light-emitting element 150D.

A self-assembly process may be performed on the backplane substrate 300A configured as described above, so that the plurality of semiconductor light-emitting elements 150D may be assembled into the plurality of subpixels PX1, PX2, and PX3 of each of the plurality of pixels PX on the substrate 310.

As an example, a plurality of red semiconductor light-emitting elements, a plurality of green semiconductor light-emitting elements, and a plurality of blue semiconductor light-emitting elements may be sequentially assembled into the plurality of subpixels PX1, PX2, and PX3 of each of the plurality of pixels PX on the substrate 310.

As another example, a plurality of red semiconductor light-emitting elements, a plurality of green semiconductor light-emitting elements, and a plurality of blue semiconductor light-emitting elements may be simultaneously assembled into a plurality of subpixels PX1, PX2, and PX3 of each of a plurality of pixels PX on the substrate 310. To this end, a plurality of red semiconductor light-emitting elements, a plurality of green semiconductor light-emitting elements, and a plurality of blue semiconductor light-emitting elements may be dropped into a fluid in the chamber and mixed with each other. Then, the same self-assembly process may be performed, so that a plurality of red semiconductor light-emitting elements, a plurality of green semiconductor light-emitting elements, and a plurality of blue semiconductor light-emitting elements may be simultaneously assembled into a plurality of subpixels PX1, PX2, and PX3 of each of a plurality of pixels PX on the substrate 310.

For the simultaneous self-assembly, each of the red semiconductor light-emitting elements, the green semiconductor light-emitting elements, and the blue semiconductor light-emitting elements may have exclusivity with respect to each other. That is, the shapes or sizes of the red semiconductor light-emitting elements, the green semiconductor light-emitting elements, and the blue semiconductor light-emitting elements may be different from each other. For example, the red semiconductor light-emitting element may have a circular shape, the green semiconductor light-emitting element may have a first elliptical shape having a first minor axis and a first major axis, and the blue semiconductor light-emitting element may have a second elliptical shape. At this time, the second elliptical shape may have a second minor axis smaller than the first minor axis and a second major axis greater than the first major axis.

Meanwhile, after the semiconductor light-emitting element 150D is assembled, the fixing member 380 may be disposed between the semiconductor light-emitting element 150D and the first insulating layer 330 within the assembly hole 340H, so that the semiconductor light-emitting element 150D may be fixed to the first insulating layer 330 by the fixing member 380. The fixing member 380 may comprise an organic material such as PAC or a photosensitive material, but is not limited thereto.

The fixing member 380 may have a shape corresponding to a shape of the semiconductor light-emitting element 150D. For example, the diameter (or width) of the fixing member 380 may be the same as the diameter (or width) of the semiconductor light-emitting element 150D, but is not limited thereto. For example, the fixing member 380 may have a shape corresponding to a shape of the first conductivity type semiconductor layer 151 of the semiconductor light-emitting element 150D and/or a shape of the electrode 154.

Meanwhile, since the anti-aggregation layer 158 is formed on the lateral part of the semiconductor light-emitting element 150D, electrical connection by a post-process may be hindered. Accordingly, after the semiconductor light-emitting element 150D is fixed by the fixing member 380, the anti-aggregation layer 158 may be removed on the lateral part of the light-emitting layer 150a of the semiconductor light-emitting element 150D, so that the lateral part of the first electrode 154, i.e., the reflective layer 154-1 and/or the magnetic layer 154-3, may be exposed to the outside. Meanwhile, the anti-aggregation layer 158 on the lower side of the light-emitting layer 150a of the semiconductor light-emitting element 150D may remain as is without being removed, but is not limited thereto. In this instance, a lower surface of the anti-aggregation layer 158 of the semiconductor light-emitting element 150D may be in contact with an upper surface of the fixing member 380.

Thereafter, an etching process may be performed so that the partition wall 340 may be removed. Thereafter, an electrical connection to the semiconductor light-emitting element 150D may be performed using a post-process. That is, a connecting electrode 370 and an electrode wiring 360 may be formed using a post-process.

First, the connecting electrode 370 may be formed along the perimeter of the semiconductor light-emitting element 150D. Since the partition wall 340 is removed, the connecting electrode 370 may be easily formed without electrical disconnection.

The connecting electrode 370 may electrically connect the semiconductor light-emitting element 150D and the first assembly wiring 321 and/or the second assembly wiring 322. To this end, the first insulating layer 330 may be removed along the perimeter of the semiconductor light-emitting element 150D before forming the connecting electrode 370, so that the first assembly wiring 321 and/or the second assembly wiring 322 may be exposed to the outside. Thereafter, the connecting electrode 370 may be formed along the perimeter of the semiconductor light-emitting element 150D, so that the first electrode 154 of the semiconductor light-emitting element 150D may be connected to the first assembly wiring 321 and/or the second assembly wiring 322 by the connecting electrode 370. For example, the connecting electrode 370 may be electrically connected to a side surface of the reflective layer 154-1 and/or the magnetic layer 154-3 of the first electrode 154. Accordingly, the contact area between the connecting electrode 370 and the semiconductor light-emitting element 150D may increase, so that the electrical characteristics or optical characteristics of the semiconductor light-emitting element 150D can be improved. That is, low-voltage operation is possible, and the light emission efficiency and the light luminance can be improved.

The connecting electrode 370 may be formed using an electroplating or sputtering method.

As an example, the connecting electrode 370 may be formed using an electroplating process. That is, first, a mask member such as a PR pattern may be formed on the remaining region except for the exposed first assembly wiring 321 and/or second assembly wiring 322 and the lateral part of the semiconductor light-emitting element 150D. Thereafter, a plating target, for example, a substrate 310, may be immersed in an electrolyte, and then the first assembly wiring 321 and/or the second assembly wiring 322 may be connected to a cathode electrode and a voltage may be applied. Thus, a metal film may be coated on the first assembly wiring 321 and/or the second assembly wiring 322, so that the connecting electrode 370 may be formed.

As the metal film is coated on the first assembly wiring 321 and/or the second assembly wiring 322 and gradually becomes thicker, the connecting electrode 370 may be formed along the perimeter of the semiconductor light-emitting element 150D in the assembly hole 340H as well as on the lower side of the semiconductor light-emitting element 150D.

As another example, a metal film 440 may be formed and patterned on the substrate 310 using a sputtering process, so that the connecting electrode 370 may be formed along the perimeter of the semiconductor light-emitting element 150D in the assembly hole 340H. Alternatively, a PR pattern may be formed in advance so that the metal film 440 may be formed only in a specific region, that is, only on the first assembly wiring 321 and/or the second assembly wiring 322 and the lateral part of the semiconductor light-emitting element 150D.

Although not illustrated, instead of the connecting electrode 370, another electrode wiring may be spaced apart from the electrode wiring 360 and connected to the lateral part of the semiconductor light-emitting element 150D through the second insulating layer 350. In this instance, the electrode wiring 360 and another electrode may be formed on the same layer, that is, the second insulating layer 350, by the same process, but are not limited thereto.

Meanwhile, the second insulating layer 350 may be disposed on the first insulating layer 330. The second insulating layer 350 may be disposed on the connecting electrode 370 as well as the first insulating layer 330. In addition, the second insulating layer 350 may be disposed along the perimeter of the lateral part of the semiconductor light-emitting element 150D. The semiconductor light-emitting element 150D may be firmly fixed by the second insulating layer 350. The second insulating layer 350 may not be disposed on the upper side of the semiconductor light-emitting element 150D. Alternatively, although not illustrated, the second insulating layer 350 may be disposed on the upper side of the semiconductor light-emitting element 150D.

Meanwhile, for electrical connection of the upper side of the semiconductor light-emitting element 150D, the passivation layer 157 on the upper side of the semiconductor light-emitting element 150D may be removed. In this instance, the upper surface of the second electrode 155 of the semiconductor light-emitting element 150D and the upper surface of the second insulating layer 350 may be positioned on the same horizontal line, but are not limited thereto.

The second insulating layer 350 may be a planarizing layer for easily forming the electrode wiring 360 or other layers. Accordingly, the upper surface of the second insulating layer 350 may have a straight plane, but are not limited thereto. The first insulating layer 330 and the second insulating layer 350 may each comprise an organic material or an inorganic material. For example, the first insulating layer 330 may comprise an inorganic material, and the second insulating layer 350 may comprise an organic material.

The electrode wiring 360 may be disposed on the second insulating layer 350, so that the electrode wiring 360 may extend on the second insulating layer 350 and be electrically connected to the upper side of the semiconductor light-emitting element 150D, i.e., the second electrode 155. Since the upper surface of the second electrode 155 of the semiconductor light-emitting element 150D and the upper surface of the second insulating layer 350 are positioned on the same horizontal line, the electrode wiring 360 may be deposited on the substrate 310 and patterned to have a straight pattern and be disposed on the second insulating layer 350 and the second electrode 155 of the semiconductor light-emitting element 150D.

By completing such an electrical connection, the semiconductor light-emitting element 150D may emit light by the voltage (or current) supplied to the electrode wiring 360 and the first assembly wiring 321 and/or the second assembly wiring 322.

Meanwhile, the display device described above may be a display panel. That is, in the embodiment, the display device and the display panel may be understood to have the same meaning. In the embodiment, the display device in a practical sense may comprise a display panel and a controller (or processor) that may control the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### Industrial Applicability

The embodiment may be adopted in the display field for displaying images or information. The embodiment may be adopted in the display field for displaying images or information using a semiconductor light-emitting element. The semiconductor light-emitting element may be a micro-level semiconductor light-emitting element or a nano-level semiconductor light-emitting element.

For example, the embodiment may be adopted in a TV, signage, a mobile terminal such as a mobile phone or a smart phone, a computer display such as a laptop or a desktop, a head-up display (HUD) for an automobile, a backlight unit for a display, a display for extended reality (XR) such as AR, VR, and mixed reality (MR), a light source, etc.

1. A semiconductor light-emitting element, comprising:
a light-emitting layer;
a passivation layer configured to surround the light-emitting layer;
a first electrode under the light-emitting layer; and
a second electrode on the light-emitting layer,
wherein the first electrode comprises:
a reflective layer;
an adhesive layer between the light-emitting layer and the reflective layer; and
a magnetic layer on the reflective layer,
wherein the reflective layer comprises a first reflective laver on a side surface of the light-emitting layer, and
wherein a part of the first reflective laver is disposed on the passivation laver.

2. The semiconductor light-emitting element of claim 1,
wherein the adhesive layer is disposed between the side surface of the light-emitting layer and the first reflective layer.

3. The semiconductor light-emitting element of claim 1, wherein the reflective layer comprises a second reflective layer on a lower surface of the light-emitting layer, and
wherein the adhesive layer is disposed between the lower surface of the light-emitting layer and the second reflective layer.

4. The semiconductor light-emitting element of claim 1, wherein the adhesive layer is disposed along an edge region of a lower surface of the light-emitting layer.

5. The semiconductor light-emitting element of claim 1, wherein the adhesive layer comprises a transparent conductor.

6. The semiconductor light-emitting element of claim 1, wherein the adhesive layer has a hydrophilic surface.

7. The semiconductor light-emitting element of claim 1, wherein the adhesive layer has a thickness of 20 nm or less.

8. (canceled)

9. The semiconductor light-emitting element of claim 1, comprising:
an anti-aggregation layer under the first electrode.

10. The semiconductor light-emitting element of claim 9, wherein the anti-aggregation layer comprises an insulator.

11. The semiconductor light-emitting element of claim 9, wherein the anti-aggregation layer is configured to cover the first electrode.

12. The semiconductor light-emitting element of claim 9, wherein a part of the anti-aggregation layer is disposed on the passivation layer.

13. The semiconductor light-emitting element of claim 9, wherein the anti-aggregation layer has a thickness of 1/10 or less of a thickness of the passivation layer.

14. A display device comprising the semiconductor light-emitting element of claim 1.
